(19) United States
(12) Patent Application Publication
(10) Pub. No.: US 2024/0120265 A1
(43) Pub. Date: Apr. 11, 2024

(54) CIRCUIT BOARD AND PACKAGE SUBSTRATE COMPRISING SAME

(71) Applicant: LG INNOTEK CO., LTD., Seoul (KR)

(72) Inventors: Sang Young LEE, Seoul (KR); Dong Min KIM, Seoul (KR); Jin Soo BAE, Seoul (KR)

(73) Assignee: LG INNOTEK CO., LTD., Seoul (KR)

(21) Appl. No.: 18/274,946

(22) PCT Filed: Jan. 28, 2022
(86) PCT No.: PCT/KR2022/001645

§ 371 Date: Jul. 28, 2023

(30) Foreign Application Priority Data
Jan. 29, 2021 (KR) 10-2021-0012899

(51) Int. Cl. H01L 23/498; H01L 21/48

(52) U.S. Cl. CPC H01L 23/49838; H01L 21/4857; H01L 23/49822

(57) ABSTRACT

A circuit board according to an embodiment comprises an insulating layer; an electrode layer disposed on the insulating layer; and a protective layer disposed on the insulating layer and including an opening vertically overlapping at least a portion of an upper surface of the electrode layer; wherein the electrode layer includes: a first layer disposed on the insulating layer; a second layer disposed on the first layer; a third layer disposed on the second layer; and a fourth layer disposed on the third layer, wherein a width of the second layer is greater than a width of the third layer, wherein a thickness of the second layer is greater than a thickness of the third layer, and wherein a height of an upper surface of the protective layer is equal to or less than a height of an upper surface of the third layer.

### TECHNICAL FIELD

An embodiment relates to a circuit board, and more particularly, to a circuit board including a pad having improved bonding properties with an adhesive member and a package substrate including the same.

### BACKGROUND ART

A line width of circuits is becoming smaller as the miniaturization, weight reduction, and integration of electronic components accelerate. In particular, as design rules of semiconductor chips are integrated on a nanometer scale, a circuit line width of a package substrate or a circuit board on which a semiconductor chip is mounted is reduced to several micrometers or less.

In order to increase the degree of circuit integration of the circuit board, that is, various methods have been proposed in order to miniaturize the circuit line width. In order to prevent loss of circuit line width in the etching step to form a pattern after copper plating, a semi-additive process (SAP) method and a modified semi-additive process (MSAP) have been proposed.

Since then, in order to realize a finer circuit pattern, an Embedded Trace Substrate (hereinafter referred to as ‘ETS’) method, which buries and embeds copper foil in an insulating layer, has been used in this technology field. The ETS method is manufactured by embedding the copper foil circuit in the insulating layer instead of forming it on the surface of the insulating layer. For this reason, there is no circuit loss due to etching, so it is advantageous to refine the circuit pitch.

Meanwhile, recently, efforts are being made to develop an improved 5th generation (5G) communication system or a pre-5G communication system in order to meet the demand for wireless data traffic. Here, the 5G communication system uses ultra-high frequency (mmWave) bands (sub 6 gigabytes (6 GHz), 28 gigabytes 28 GHz, 35 gigabytes 35 GHz or higher frequencies) to achieve high data rates.

And, in order to alleviate the path loss of radio waves in the very high frequency band and increase the propagation distance of radio waves, aggregation technologies such as beamforming, massive MIMO, and array antenna are being developed in the 5G communication system. Various chips constituting the AP module are mounted on a circuit board applied to such a communication system of 5G or higher (6G, 7G˜etc.), and the circuit board includes pads for mounting these chips. Performance of the 5G or higher communication system may be determined according to characteristics of a chip mounted on the circuit board. In addition, performance improvement of a final product may be determined by bonding between the mounted chip and the pad of the circuit board connected thereto.

Accordingly, there is a demand for a circuit board having a structure capable of improving bonding properties of pads connected to the chip.

### DISCLOSURE

### Technical Problem

The embodiment provides a circuit board having a novel structure and a package substrate including the circuit board.

Specifically, the embodiment provides a circuit board including an electrode layer having improved bonding properties with a chip and a package substrate including the circuit board.

In addition, the embodiment provides a circuit board having improved bonding strength between a protective layer and an electrode layer, and a package substrate including the circuit board.

The technical problem to be solved in the embodiment is not limited to the technical problem mentioned above, and another technical problem not mentioned will be clearly understood by those of ordinary skill in the art to which the present invention belongs from the following description.

### Technical Solution

A circuit board according to an embodiment comprises an insulating layer; an electrode layer disposed on the insulating layer; and a protective layer disposed on the insulating layer and including an opening vertically overlapping at least a portion of an upper surface of the electrode layer; wherein the electrode layer includes: a first layer disposed on the insulating layer; a second layer disposed on the first layer; a third layer disposed on the second layer; and a fourth layer disposed on the third layer, wherein a width of the second layer is greater than a width of the third layer, wherein a thickness of the second layer is greater than a thickness of the third layer, and wherein a height of an upper surface of the protective layer is equal to or less than a height of an upper surface of the third layer.

In addition, the first layer is a seed layer disposed on an upper surface of the insulating layer, wherein the second layer is a first pattern layer of a circuit pattern layer disposed on the seed layer, wherein the third layer is a second pattern layer of the circuit pattern layer disposed on the first pattern layer of the circuit pattern layer, and wherein the fourth layer is a surface treatment layer disposed on the second pattern layer of the circuit pattern layer.

In addition, the electrode layer is a pad on which a chip is mounted.

In addition, the second layer of the electrode layer includes a same metal material as a metal material of the third layer of the electrode layer.

In addition, the second layer of the electrode layer has a greater width than a width of the fourth layer of the electrode layer.

In addition, the thickness of the second layer of the electrode layer is greater than a thickness of the fourth layer of the electrode layer.

In addition, the upper surface of the protective layer is positioned lower than the third layer of the electrode layer, and wherein the third layer of the electrode layer includes a protruding region protruding from the upper surface of the protective layer.

In addition, the fourth layer of the electrode layer includes: a first portion disposed on an upper surface of the third layer of the electrode layer; and a second portion extending from the first portion and disposed on a side surface of the protruding region of the third layer.

In addition, the fourth layer of the electrode layer includes: a first portion disposed on an upper surface of the third layer of the electrode layer; and a second portion extending from the first portion and disposed on the upper surface of the protective layer.

In addition, wherein at least one side surface of the second layer and the third layer of the electrode layer includes a curved surface.

### Advantageous Effects

An embodiment includes a circuit pattern layer. The circuit pattern layer includes an electrode layer that is a pad on which a chip is mounted. The electrode layer may include first to fourth layers. For example, the electrode layer may include a seed layer, a first pattern layer, a second pattern layer, and a surface treatment layer. In this case, the surface treatment layer may include a first portion disposed on an upper surface of the second pattern layer, and a second portion extending from the first portion and disposed on the upper surface of the protective layer. Accordingly, the embodiment can secure a wide space for arranging an adhesive member (not shown) for mounting chips by the surface treatment layer including the second portion, and thereby improve chip bonding. That is, in the embodiment, the width of the surface treatment layer is greater than the width of the second pattern layer, and thus a contact area with the adhesive member can be widened. Accordingly, according to the embodiment, the contact area with the adhesive member can be increased, and accordingly, the bonding property with the adhesive member such as a solder ball or a wire can be further improved.

In addition, since the second portion is disposed on the upper surface of the protective layer, the protective layer can support the second portion when an adhesive member (not shown) is disposed for mounting a chip. Accordingly, the embodiment can prevent the surface treatment layer from being damaged due to the adhesive member, unlike the conventional overhang structure (for example, a structure in which an end of the surface treatment layer is spaced apart without contacting the protective layer, the first pattern layer, and the second pattern layer).

In addition, in the embodiment, the upper surface of the second pattern layer may be positioned higher than the upper surface of the protective layer. Accordingly, the embodiment can prevent the resin of the protective layer from remaining on the upper surface of the second pattern layer. Accordingly, in the embodiment, the entire upper surface of the pad can be used as a space for connection with the chip. Accordingly, the embodiment can improve circuit integration and improve electrical and physical reliability. Furthermore, the embodiment allows the surface treatment layer to be disposed on a part of the side surface of the protruding second pattern layer. Accordingly, the embodiment can improve the contact area between the surface treatment layer and the second pattern layer. Therefore, in the embodiment, it is possible to solve the problem of delamination in which the surface treatment layer is separated from the second pattern layer, and thereby improve electrical and physical reliability.

In addition, in the embodiment, at least one side surface of the seed layer, the first pattern layer, and the second pattern layer constituting the pad has a rounded curved surface. Accordingly, in an embodiment, a contact area between the seed layer, the first pattern layer, and the second pattern layer and the protective layer may be increased. Accordingly, the embodiment can solve the problem of lifting between the pad and the protective layer (eg, forming an air layer between the protective layer and the pad) in a process of forming the protective layer. The embodiment can solve the delamination problem in which the protective layer is separated from the pad, and further improve the overall physical reliability and electrical reliability of the circuit board.

### DESCRIPTION OF DRAWINGS

FIG. 1 is a view showing a circuit board according to a first embodiment.

FIG. 2 is an enlarged view of an electrode layer of FIG. 1.

FIGS. 3 to 15 are views showing a first method for manufacturing the circuit board shown in FIG. 1 in order of process.

FIGS. 16 and 17 are views for explaining a second method for manufacturing the circuit board shown in FIG. 1.

FIG. 18 is a view showing a circuit board according to a second embodiment.

FIG. 19 is a view showing a circuit board according to a third embodiment.

FIG. 20 is a view showing a package substrate according to an embodiment.

### MODES OF THE INVENTION

Hereinafter, embodiments disclosed in the present specification will be described in detail with reference to the accompanying drawings, but identical or similar elements are denoted by the same reference numerals regardless of reference numerals, and redundant descriptions thereof will be omitted. The suffixes “module” and “portion” for the components used in the following description are given or used interchangeably in consideration of only the ease of writing the specification, and do not have meanings or roles that are distinguished from each other by themselves. In addition, in describing the embodiments disclosed in the present specification, if it is determined that a detailed description of related known technologies may obscure the subject matter of the embodiments disclosed in the present specification, the detailed description thereof will be omitted. In addition, the accompanying drawings are only for making it easier to understand the embodiments disclosed in the present specification, and the technical idea disclosed in the present specification is not limited by the accompanying drawings, and this should be understood to include all changes, equivalents, or substitutes included in the spirit and scope of the present invention.

Terms including ordinal numbers such as first and second may be used to describe various elements, but the elements are not limited by the terms. The above terms are used only for the purpose of distinguishing one component from another component.

When a component is referred to as being “contacted” or “connected” to another component, it may be directly connected or connected to the other component, but other components may exist in the middle. On the other hand, when a component is referred to as being “directly contacted” or “directly connected” to another component, it should be understood that there is no other component in the middle.

Singular expressions include plural expressions unless the context clearly indicates otherwise.

In the present application, terms such as “comprises” or “have” are intended to designate the presence of features, numbers, steps, actions, components, parts, or combinations thereof described in the specification, but one or more other features. It is to be understood that the presence or addition of elements or numbers, steps, actions, components, parts, or combinations thereof, does not preclude in advance the possibility of being excluded.

Hereinafter, embodiments of the present invention will be described in detail with reference to the accompanying drawings.

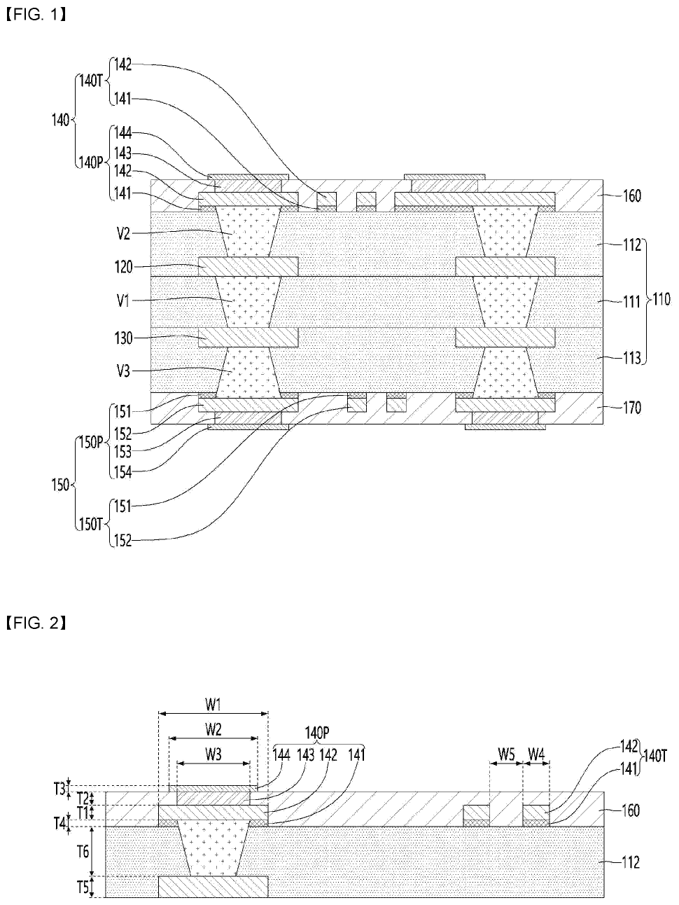

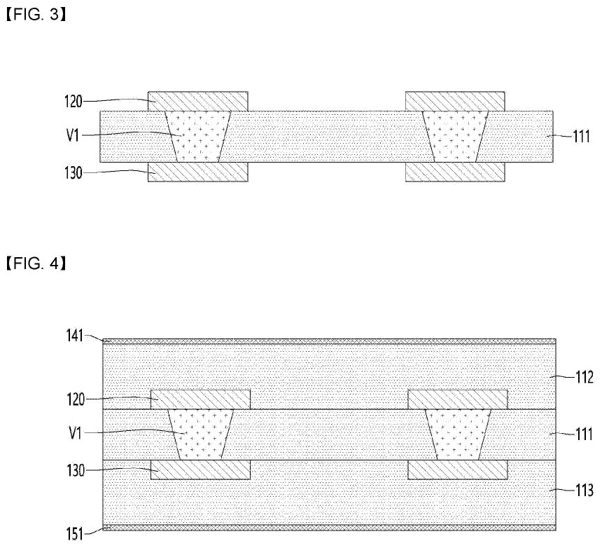

FIG. 1 is a view showing a circuit board according to a first embodiment, and FIG. 2 is an enlarged view of an electrode layer of FIG. 1.

Referring to FIGS. 1 and 2, the circuit board includes an insulating layer 110, a circuit pattern layer, a via, and a protective layer.

The insulating layer 110 may have a multi-layer structure. For example, the insulating layer 110 may include a first insulating layer 111, a second insulating layer 112, and a third insulating layer 113. In this case, the circuit board is illustrated as having a three-layer structure based on the number of insulating layers, but the embodiment is not limited thereto. For example, the circuit board may have a structure of two or less layers based on the number of insulating layers, or may have a structure of four or more layers.

For example, the first insulating layer 111 may be an inner insulating layer disposed at an inner side in a multi-layer structure. In addition, the second insulating layer 112 may be a first outermost insulating layer disposed at a first outermost side in a multilayer structure. In addition, the third insulating layer 113 may be a second outermost insulating layer disposed at a second outermost side in a multilayer structure. In addition, the inner insulating layer is illustrated as being composed of one layer, but may be composed of two or more layers differently.

The insulating layer 110 is a substrate on which an electric circuit capable of changing wiring is formed, and may include all of a printed circuit board and an insulating substrate made of an insulating material capable of forming circuit patterns on the surface thereof.

For example, at least one of the insulating layer 110 may be rigid or may be flexible. For example, at least one of the insulating layer 110 may include glass or plastic. In detail, at least one of the insulating layer 110 may include chemically strengthened/semi-tempered glass such as soda lime glass or aluminosilicate glass, or strengthened or flexible plastic such as polyimide (PI), polyethylene terephthalate (PET), propylene glycol (PPG) and polycarbonate (PC), or sapphire.

In addition, at least one of the insulating layer 110 may include an optical isotropic film. For example, at least one of the insulating layer 110 may be includes COC (cyclic Olefin Copolymer), COP (Cyclic Olefin Polymer), photo isotropic polycarbonate (polycarbonate, PC), or photo isotropic polymethyl methacrylate (PMMA).

In addition, at least one of the insulating layers 110 may be formed of a material including an inorganic filler and an insulating resin. For example, the material constituting the insulating layer 110 may be a thermosetting resin such as an epoxy resin, a silica with thermoplastics such as polyimide, a resin containing a reinforcing material such as inorganic fillers such as alumina, specifically ABF (Ajinomoto Build-up Film), FR-4, BT (Bismaleimide Triazine), PID (Photo Imageable Dielectric resin), BT, or the like.

In addition, at least one of the insulating layer 110 may be bent while having a partially curved surface. That is, at least of the insulating layer 110 may be bent while having a partially flat surface and a partially curved surface. In detail, at least of the insulating layer 110 may have a curved end while having a curved surface, or may have a surface including a random curvature and may be bent or curved.

A circuit pattern layer may be disposed on a surface of the insulating layer 110.

For example, a first circuit pattern layer 120 may be disposed on a first surface of the first insulating layer 111. For example, a second circuit pattern layer 130 may be disposed on a second surface of the first insulating layer 111. For example, a third circuit pattern layer 140 may be disposed on a first surface of the second insulating layer 112. For example, the fourth circuit pattern layer 150 may be disposed on a second surface of the third insulating layer 113. The first circuit pattern layer 120 and the second circuit pattern layer 130 may be referred to as an inner circuit pattern layer disposed on a surface of the inner insulating layer. In addition, the third circuit pattern layer 140 and the fourth circuit pattern layer 150 may be referred to as an outer or outermost circuit pattern layer disposed on an outermost insulating layer.

The first to fourth circuit pattern layers 120, 130, 140, and 150 perform a signal transmission function. The first to fourth circuit pattern layers 120, 130, 140, and 150 may also be referred to as ‘an electrode layer’.

In this case, the first circuit pattern layer 120, the second circuit pattern layer 130, the third circuit pattern layer 140, and the fourth circuit pattern layer 150 are a wiring that transmits an electrical signal and may be formed of a metal material having high electrical conductivity. To this end, the first circuit pattern layer 120, the second circuit pattern layer 130, the third circuit pattern layer 140, and the fourth circuit pattern layer 150 may be formed of at least one metal material selected from gold (Au), silver (Ag), platinum (Pt), titanium (Ti), tin (Sn), copper (Cu), and zinc (Zn). In addition, the first circuit pattern layer 120, the second circuit pattern layer 130, the third circuit pattern layer 140, and the fourth circuit pattern layer 150 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first circuit pattern layer 120, the second circuit pattern layer 130, the third circuit pattern layer 140, and the fourth circuit pattern layer 150 may be formed of copper (Cu), which has high electrical conductivity and is relatively inexpensive.

The first circuit pattern layer 120, the second circuit pattern layer 130, the third circuit pattern layer 140, and the fourth circuit pattern layer 150 may be formed by an additive process, a subtractive process, a modified semi additive process (MSAP) and a semi additive process (SAP) method, which is a typical circuit board manufacturing process, and a detailed description thereof will be omitted herein.

Meanwhile, each of the third circuit pattern layer 140 and the fourth circuit pattern layer 150 includes a trace and a pad. The trace and the pad may be classified based on any one of a planar shape and a width. For example, a plane shape of the trace may be a square shape. In addition, the planar shape of the pad may be a circular shape. For example, at least a portion of a circumference of an upper surface of the pad may include a curved surface. A width of the trace may be smaller than a width of the pad. That is, the trace may serve to connect a plurality of pads. Accordingly, the trace may have a fine line width. In addition, the pad may function as a mounting pad on which a chip is mounted. Accordingly, the pad may have a width greater than or equal to a certain level to provide a chip mounting space.

Specifically, the third circuit pattern layer 140 may include a pad 140P and a trace 140T. In addition, the fourth circuit pattern layer 150 may include a pad 150P and a trace 150T. The traces 140T and 150T refer to long line-type wires that transmit an electrical signal. And, the pads 140P and 150P may mean mounting pads on which components such as chips are mounted, or core pads or BGA pads for connection with an external board. Accordingly, the pad 140P may also be referred to as a ‘first pad’, and the pad 150P may also be referred to as a ‘second pad’. The pads 140P and 150P may also be referred to as ‘an electrode layer’.

Specifically, the pad 140P of the third circuit pattern layer 140 may be a mounting pad on which a component such as a chip is mounted. In addition, the pad 150P of the fourth circuit pattern layer 140 may be a core pad or a BGA pad for connection to an external board, but is not limited thereto. Meanwhile, the pad 140P of the third circuit pattern layer 140 may have a narrower width than a width of the pad 150P of the fourth circuit pattern layer 150.

A surface of the pad 140P of the third circuit pattern layer 140 may be exposed through the first protective layer 160 disposed on the first surface of the second insulating layer 112. For example, the first protective layer 160 may include an opening (not shown). In addition, the opening of the first protective layer 160 may vertically overlap the upper surface of the pad 140P of the third circuit pattern layer 140. In addition, a surface of the pad 150P of the fourth circuit pattern layer 150 may be exposed through the second protective layer 170 disposed on the second surface of the third insulating layer 113. For example, the second protective layer 170 may include an opening (not shown). In addition, the opening of the second protective layer 170 may vertically overlap a lower surface of the pad 150P of the fourth circuit pattern layer 150.

The third circuit pattern layer 140 may have a multi-layer structure. In this case, the pad 140P and the trace 140T of the third circuit pattern layer 140 may have a different layer structure. For example, the number of layers of the pad 140P may be greater than the number of layers of the trace 140T. For example, the trace 140T may include only some of a plurality of layers constituting the pad 140P.

For example, the pad 140P of the third circuit pattern layer 140 may include first to fourth layers. In addition, the trace 140T of the third circuit pattern layer 140 may include only the first layer and the second layer.

For example, the pad 140P of the third circuit pattern layer 140 may have a four-layer structure. In addition, the trace 140T of the third circuit pattern layer 140 may have a two-layer structure.

In this case, for convenience of explanation, the first to fourth layers will be referred to as a seed layer, a first pattern, a second pattern, and a surface treatment layer. For example, the seed layer described below may also be referred to as a ‘first layer’. For example, the first pattern described below may also be referred to as a ‘second layer’. For example, the second pattern described below may also be referred to as a ‘third layer’. For example, the surface treatment layer described below may also be referred to as a ‘fourth layer’. And, this may be equally applied to the fourth circuit pattern layer.

For example, the pad 140P of the third circuit pattern layer 140 may include a first pattern layer 142 disposed on a first surface of the second insulating layer 112 and a second pattern layer 143 disposed on the first pattern layer 142. In the embodiment, the pad 140P of the third circuit pattern layer 140 may have a two-layer structure. Accordingly, in the embodiment, the pad 140P of the third circuit pattern layer 140 protrudes with a predetermined height or more based on the first surface of the second insulating layer 112. Accordingly, in the embodiment, the pad 140P of the third circuit pattern layer 140 has the predetermined height or more, and accordingly, it can improve the ease of mounting the chip.

The first pattern layer 142 and the second pattern layer 143 may include the same metal material as each other. For example, the first pattern layer 142 may include copper. In addition, the second pattern layer 143 may include copper, which is the same metal material as the first pattern layer 142.

In addition, the pad 140P of the third circuit pattern layer 140 may include a seed layer 141 disposed between the first surface of the second insulating layer 112 and the first pattern layer 142. The seed layer 141 may be a seed layer used to form the first pattern layer 142 and the second pattern layer 143. For example, the first pattern layer 142 and the second pattern layer 143 may be formed by an electroplating process. Accordingly, the seed layer 141 may be a seed layer for electroplating each of the first pattern layer 142 and the second pattern layer 143.

The pad 140P of the third circuit pattern layer 140 may include a surface treatment layer 144 disposed on the second pattern layer 143. The surface treatment layer 144 may be formed to protect a surface of the pad 140P or to improve a bonding property of the pad 140P. The surface treatment layer 144 may include gold (Au). For example, the surface treatment layer 144 may include only a gold metal layer. In addition, the gold metal layer may be directly formed on the second pattern layer 143 including copper. Alternatively, the surface treatment layer 144 may be an ENEPIG layer. For example, the surface treatment layer 144 may include a nickel metal layer, a palladium metal layer, and a gold metal layer.

Meanwhile, the trace 140T of the third circuit pattern layer 140 may include only some of the layers constituting the pad 140P. For example, the trace 140T of the third circuit pattern layer 140 may include the seed layer 141 and the first pattern layer 142. Accordingly, in the embodiment, a portion of the pad 140P and the trace 140T of the third circuit pattern layer 140 may be formed by forming the seed layer 141 and the first pattern layer 142. In addition, in the embodiment, the pad 140P may be formed by forming the second pattern layer 143 and the surface treatment layer 144 on a region corresponding to the pad 140P among the formed first pattern layer 142.

The pad 150P of the fourth circuit pattern layer 150 may have substantially the same structure as the pad 140P of the third circuit pattern layer 140. For example, the pad 150P of the fourth circuit pattern layer 150 may include a seed layer 151, a first pattern layer 152, a second pattern layer 153, and a surface treatment layer 154. In this case, the seed layer 151, the first pattern layer 152, the second pattern layer 153 and the surface treatment layer 154 constituting the pad 150P of the fourth circuit pattern layer 150 has substantially the same layer structure as the seed layer 141, the first pattern layer 142, the second pattern layer 143, and the surface treatment layer 144 constituting the pad 140P of the third circuit pattern layer 140, and accordingly, a detailed description thereof will be omitted.

In addition, the trace 150T of the fourth circuit pattern layer 150 corresponds to the trace 140T of the third circuit pattern layer 140, and may include a seed layer 151 and a first pattern layer 152, which are parts of layers constituting the pad 150P.

The third circuit pattern layer may be a mounting pad on which a component such as a chip is mounted. The fourth circuit pattern layer may be a core pad or a BGA pad for connection with an external board. A pad of the fourth circuit pattern layer 150 may have a wider width than a width of a pad of the third circuit pattern layer.

A first protective layer 160 may be disposed on the first surface of the second insulating layer 112. The first protective layer 160 may include a solder resist. The first protective layer 160 may include an opening (not shown) exposing a surface of the pad 140P of the third circuit pattern layer 140. For example, the first protective layer 160 may expose the surface of the second pattern layer 143 constituting the pad 140P of the third circuit pattern layer 140.

The first protective layer 160 may be disposed to cover a side surface of the seed layer 141 of the third circuit pattern layer 140. In addition, the first protective layer 160 may be disposed to cover a side surface of the first pattern layer 142 of the pad 140P. In addition, the first protective layer 160 may cover a portion of an upper surface of the first pattern layer 142 of the pad 140P. In addition, the first protective layer 160 may be disposed to cover a side surface of the second pattern layer 143 of the pad 140P.

In the first embodiment, an upper surface of the first protective layer 160 and an upper surface of the second pattern layer 143 of the third circuit pattern layer 140 may be positioned on the same plane.

Correspondingly, a second protective layer 170 may be disposed on the second surface of the third insulating layer 113. The second protective layer 170 may include a solder resist. The second protective layer 170 may include an opening (not shown) exposing a surface of the pad 150P of the fourth circuit pattern layer 150. For example, the second protective layer 170 may expose the surface of the second pattern layer 153 constituting the pad 150P of the fourth circuit pattern layer 150.

The second protective layer 170 may be disposed to cover a side surface of the seed layer 151. In addition, the second protective layer 170 may be disposed to cover a side surface of the first pattern layer 152 of the pad 150P of the fourth circuit pattern layer 150. In addition, the second protective layer 170 may cover a part of the lower surface of the first pattern layer 152 of the pad 150P of the fourth circuit pattern layer 150. In addition, the second protective layer 170 may be disposed to cover a side surface of the second pattern layer 153 of the pad 150P of the fourth circuit pattern layer 150.

In addition, in the first embodiment, the lower surface of the second protective layer 170 and the lower surface of the second pattern layer 153 of the pad 150P of the fourth circuit pattern layer 150 may be positioned on the same plane.

Meanwhile, the circuit board of the embodiment includes a through electrode. The through electrode may electrically connect circuit pattern layers disposed on different layers. For example, the through electrode may be referred to as a ‘via’ for electrical connection between different circuit pattern layers. Accordingly, hereinafter, the through electrode will be referred to as a ‘via’ and described.

For example, a first via V1 may be formed in the first insulating layer 111. The first via V1 passes through the first insulating layer 111 and thus can electrically connect the first circuit pattern layer 120 and the second circuit pattern layer 130. For example, a second via V2 may be formed in the second insulating layer 112. The second via V2 passes through the second insulating layer 112 and thus can electrically connect the first circuit pattern layer 120 and the third circuit pattern layer 140. For example, a third via V3 may be formed in the third insulating layer 113. The third via V3 passes through the third insulating layer 113 and thus can electrically connect the second circuit pattern layer 130 and the fourth circuit pattern layer 150.

The vias V1, V2, and V3 as described above may be formed by filling an inside of a via hole formed in each insulating layer with a metal material. The via hole may be formed by any one of mechanical processing, laser processing, and chemical processing. When the via hole is formed by mechanical processing, methods such as milling, drilling, and routing may be used, and when the via hole is formed by laser processing, a UV or CO₂ laser method may be used, and when the via hole is formed by chemical processing, drugs containing amino silane, ketones, etc. may be used, and the like, and accordingly, the insulating layer may be opened.

When the via hole is formed, the vias V1, V2 and V3 may be formed by filling the inside of the via hole with a conductive material. The metal material forming the vias V1, V2, and V3 may be any one material selected from Cu, Ag, Sn, Au, Ni, and Pd. In addition, the metal material may be filled using any one or a combination of electroless plating, electrolytic plating, screen printing, sputtering, evaporation, ink jetting and dispensing.

As described above, each of the pads 140P and 150P of the third circuit pattern layer 140 and the fourth circuit pattern layer 150 includes a seed layer, a first pattern, a second pattern, and a surface treatment layer. Hereinafter, its structure will be described in detail. However, the pad 150P of the fourth circuit pattern layer 150 has substantially the same layer structure as the pad 140P of the third circuit pattern layer 140, and accordingly, the structure of the pad 140P of the third circuit pattern layer 140 will be mainly described.

As shown in FIG. 2, the third circuit pattern layer 140 includes a pad 140P and a trace 140T. In addition, the pad 140P includes a seed layer 141, a first pattern layer 142, a second pattern layer 143, and a surface treatment layer 144. In addition, the trace 140T may include a seed layer 141 and a first pattern layer 142. For example, the pad 140P and the trace 140T of the third circuit pattern layer 140 may have different layer structures.

The first pattern layer 142 may have a first thickness Ti. For example, the first thickness T1 of the first pattern layer 142 may satisfy a range of 7 μm to 17 μm. For example, the first thickness T1 of the first pattern layer 142 may satisfy a range of 9 μm to 15 μm. For example, the first thickness T1 of the first pattern layer 142 may satisfy a range of 10 μm to 13 μm. Here, the first pattern layer 142 may be a pattern constituting the pad 140P and the trace 140T.

The second pattern layer 143 may be disposed on the first pattern layer 142 and have a second thickness T2 smaller than the first thickness T1 of the first pattern layer 142. For example, the second thickness T2 of the second pattern layer 143 may satisfy a range of 5 μm to 15 μm. For example, the second thickness T2 of the second pattern layer 143 may satisfy a range of 7 μm to 13 μm. For example, the second thickness T2 of the second pattern layer 143 may satisfy a range of 8 μm to 11 μm.

Through this, the embodiment can reduce the overall thickness of the circuit board and reduce the distance from the uppermost surface of the second insulating layer 112, which is the outermost insulating layer of the circuit board, to the lowermost surface mounted on the circuit board, and accordingly, the overall thickness of the chip package may be reduced.

The surface treatment layer 144 may be disposed on the second pattern layer 143 and have a third thickness T3 smaller than the first thickness T1 and the second thickness T2. For example, the third thickness T3 of the surface treatment layer 144 may satisfy a range of 0.1 μm to 10 μm. For example, the third thickness T3 of the surface treatment layer 144 may satisfy a range of 0.5 μm to 8 μm. For example, the third thickness T3 of the surface treatment layer 144 may satisfy a range of 1 μm to 5 μm. However, the third thickness T3 is a thickness range of the surface treatment layer 144 when the surface treatment layer 144 is composed of the ENEPIG layer described above. For example, the surface treatment layer 144 may include a nickel (Ni) metal layer having a thickness ranging from 0.002 μm to 0.244 μm formed on the second pattern layer 143, a palladium (Pd) metal layer having a thickness ranging from 0.049 μm to 4.878 μm formed on the nickel (Ni) metal layer, and a gold (Au) metal layer having a thickness ranging from 0.049 μm to 4.478 μm formed on the palladium (Pd) metal layer. However, the embodiment is not limited thereto, and the surface treatment layer 144 may include only a gold (Au) metal layer including gold (Au). In this case, the third thickness T3 of the surface treatment layer 144 may have a thickness range lower than the thickness range described above. For example, the thickness of the gold (Au) metal layer may have a range of 0.049 μm to 4.478 μm. For example, the thickness of the gold (Au) metal layer may have a range of 0.244 μm to 3.902 μm. For example, the thickness of the gold (Au) metal layer may have a range of 0.488 μm to 2.439 μm.

The seed layer 141 is disposed between the second insulating layer 112 and the first pattern layer 142 to have a fourth thickness T4. For example, the fourth thickness T4 of the seed layer 141 may satisfy a range of 0.5 μm to 5 μm. For example, the fourth thickness T4 of the seed layer 141 may satisfy a range of 0.8 μm to 3.5 μm. For example, the fourth thickness T4 of the seed layer 141 may satisfy a range of 1.0 μm to 2.5 μm. Here, the seed layer 141 may be a pattern constituting the pad 140P and the trace 140T.

Meanwhile, the first circuit pattern layer 120 corresponding to the inner circuit pattern layer of the circuit board may have a fifth thickness T5. A fifth thickness T5 of the first circuit pattern layer 120 may correspond to a first thickness T1 of the first pattern layer 142. For example, the fifth thickness T5 of the first circuit pattern layer 120 may satisfy a range of 7 μm to 17 μm. For example, the fifth thickness T5 of the first circuit pattern layer 120 may satisfy a range of 9 μm to 15 μm. For example, the fifth thickness T5 of the first circuit pattern layer 120 may satisfy a range of 10 μm to 13 μm. However, when the first circuit pattern layer 120 includes a seed layer, the first circuit pattern layer 120 may correspond to the sum of the fifth thickness T5 and the fourth thickness T4 of the seed layer 141.

The second insulating layer 112 may have a sixth thickness T6. The sixth thickness T6 of the second insulating layer 112 may correspond to a distance from the upper surface of the first circuit pattern layer 120 to the upper surface of the second insulating layer 112. For example, the sixth thickness T6 of the second insulating layer 112 may satisfy a range of 10 μm to 30 μm. For example, the sixth thickness T6 of the second insulating layer 112 may satisfy a range of 15 μm to 25 μm. For example, the sixth thickness T6 of the second insulating layer 112 may satisfy a range of 18 μm to 23 μm.

Meanwhile, the seed layer 141 of the pad 140P, the first pattern layer 142, the second pattern layer 143, and the surface treatment layer 144 constituting the third circuit pattern layer 140 may have different widths.

The first pattern layer 142 of the pad 140P may have a first width W1. For example, the first width W1 of the first pattern layer 142 of the pad 140P may satisfy a range of 5 μm to 300 μm. For example, the first width W1 of the first pattern layer 142 of the pad 140P may satisfy a range of 70 μm to 200 μm. For example, the first width W1 of the first pattern layer 142 of the pad 140P may satisfy a range of 100 μm to 150 μm.

The second pattern layer 143 of the pad 140P has a second width W2 smaller than the first width W1 of the first pattern layer 142 and may be disposed on the first pattern layer 142 of the pad 140P. For example, the second width W2 of the second pattern layer 143 of the pad 140P may satisfy a range of 3 μm to 250 μm. For example, the second width W2 of the second pattern layer 143 of the pad 140P may satisfy a range of 50 μm to 150 μm. For example, the second width W2 of the second pattern layer 143 of the pad 140P may satisfy a range of 60 μm to 100 μm.

Accordingly, the upper surface of the first pattern layer 142 of the pad 140P may include a first portion directly contacting the lower surface of the second pattern layer 143 and a second portion other than the first portion. In addition, a second portion of the upper surface of the first pattern layer 142 may directly contact the first protective layer 160.

A portion of the pad 140P is formed under the first protective layer 160 through the second portion to prevent delamination in which the pad 140P is separated from the circuit board. In addition, the thickness of the first pattern layer 142 is greater than the thickness of the second pattern layer 143, so even if the width of the second portion is smaller than the width of the first portion, it may be possible to ensure adhesion so that the pad is not separated from the circuit board. For example, when the thickness of the first pattern layer 142 is smaller than the thickness of the second pattern layer 143, the first pattern layer 142 cannot support the second pattern layer 143 when it is connected to a chip mounted on the circuit board, and thereby the pad 140P may be separated from the circuit board. In addition, the embodiment allows forming the width of the first portion larger than the width of the second portion, and accordingly, it is possible to facilitate connection with a chip mounted on the circuit board.

The surface treatment layer 144 may be disposed on the second pattern layer 143 with a third width smaller than the first width W1 of the first pattern layer 142 of the pad 140P and greater than the second width W2 of the second pattern layer 143. For example, the third width W3 of the surface treatment layer 144 may satisfy a range of 4 μm to 280 μm. For example, the third width W3 of the surface treatment layer 144 may satisfy a range of 70 μm to 180 μm. For example, the third width W3 of the surface treatment layer 144 may satisfy a range of 80 μm to 120 μm.

Meanwhile, the first pattern layer 142 of the trace 140T may have a different width from the width of the first pattern of the pad 140P. For example, the first pattern layer 142 of the trace 140T may have a fourth width W4 narrower than the first width W1 of the first pattern of the pad 140P. The fourth width W4 of the first pattern layer 142 of the trace 140T may satisfy a range of 0.5 μm to 20 μm. For example, the fourth width W4 of the first pattern layer 142 of the trace 140T may satisfy a range of 0.8 μm to 15 μm. For example, the fourth width W4 of the first pattern layer 142 of the trace 140T may satisfy a range of 1.0 μm to 10 μm.

Meanwhile, a plurality of traces 140T may be formed on the second insulating layer 112 and spaced apart from each other. In this case, the traces 140T adjacent to each other in the plurality of traces may be spaced apart by a fifth width W5. A fifth width W5 corresponding to a spacing between the traces 140T may satisfy a range of 0.5 μm to 20 μm. For example, the fifth width W5 may satisfy a range of 0.8 μm to 15 μm. For example, the fifth width W5 may satisfy a range of 1.0 μm to 10 μm.

Meanwhile, in the first embodiment, the upper surface of the second pattern layer 143 and the upper surface of the first protective layer 160 may be positioned on the same plane.

Accordingly, the surface treatment layer 144 may include a first portion disposed on the upper surface of the second pattern layer 143 and a second portion extending from the first portion. For example, a lower surface of the surface treatment layer 144 may include a first portion of the surface treatment layer 144 in direct contact with the upper surface of the second pattern layer 143 and a second portion of the surface treatment layer 144 directly contacting the upper surface of the first protective layer 160. In this case, in the embodiment, when forming the surface treatment layer 144, an opening of a mask (not shown) has the third width W3 between the first width W1 and the second width W2. Accordingly, in the embodiment, the surface treatment layer 144 extends from the upper surface of the second pattern 143 to be partially formed on the upper surface of the first protective layer 160.

In addition, in the embodiment, the surface treatment layer 144 may be plated using the seed layer 141, the second pattern layer 142, and the second pattern layer 142 without a mask. In this case, the width of the first portion of the surface treatment layer 144 may be greater than the width of the second portion of the surface treatment layer 144. Accordingly, the embodiment allows to form a wide width of the first portion of the surface treatment layer 144 in which the surface treatment layer 144 and the second pattern layer 143 directly contact each other, it is possible to prevent the surface treatment layer 144 from being detached from the second pattern layer 143, and thus the adhesive force between the protective layer and the pad 140P can be improved. Accordingly, in the embodiment, it is possible to secure a wide arrangement space for an adhesive member (not shown) for mounting chips, and accordingly, a chip bonding property can be improved. That is, the embodiment allows the width of the surface treatment layer 144 to be great compared to the width of the second pattern layer 143, and accordingly, it can increase the contact area with an adhesive member (not shown). As a result, bonding with an adhesive member such as a solder ball or a wire can be improved.

Meanwhile, a surface roughness (Ra) of the first circuit pattern layer 120 may be different from a surface roughness (Ra) of the third circuit pattern layer 140. For example, a surface roughness (Ra) of the inner circuit pattern layer in the embodiment may be different from a surface roughness (Ra) of the outer circuit pattern layer.

For example, the first circuit pattern layer 120 may have a first surface roughness (Ra). The first surface roughness (Ra) may have a range of 0.83 μm to 1.0 μm. That is, the first circuit pattern layer 120 has roughness for improving adhesion with the second insulating layer 112, and accordingly, it may have a first surface roughness (Ra) in the range of 0.83 μm to 1.0 μm.

The third circuit pattern layer 140 may have a second surface roughness Ra, and the second surface roughness Ra may be smaller than the first surface roughness of the first circuit pattern layer 120. For example, the second surface roughness (Ra) may satisfy a range of 0.70 μm to 0.82 μm. For example, the second surface roughness (Ra) of the first pattern layer 141 may satisfy a range of 0.70 μm to 0.82 μm. For example, the second surface roughness (Ra) of the second pattern layer 142 may satisfy a range of 0.70 μm to 0.82 μm. For example, the second surface roughness (Ra) of the surface treatment layer 144 may satisfy a range of 0.70 μm to 0.82 μm.

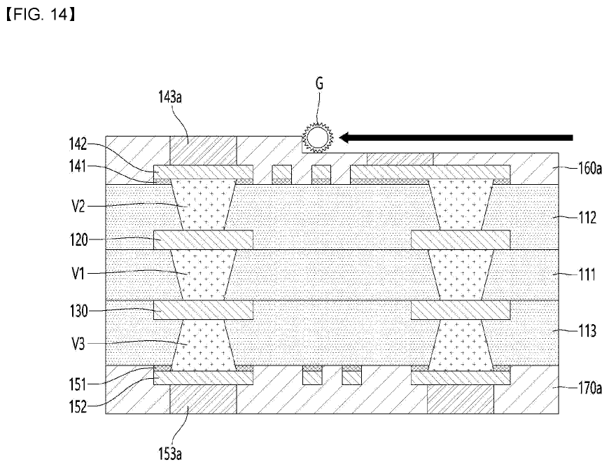

That is, in the embodiment, the second surface roughness Ra may be greater than the first surface roughness Ra. The first circuit pattern layer 120 has a relatively great surface roughness to improve adhesion with the second insulating layer 112. In addition, the pad 140P of the third circuit pattern layer 140 requires surface roughness to make contact with the contact member for connection with the protective layer or a chip mounted on the circuit board or a main printed circuit board, and may have a relatively small surface roughness. In addition, the pad 140P of the third circuit pattern layer 140 may be formed with only the roughness imparted by a process of etching the seed layer 141 as shown in FIG. 12 without a separate roughness treatment.

Meanwhile, the first protective layer 160 may have a third surface roughness Ra between the first surface roughness Ra and the second surface roughness Ra. For example, the third surface roughness (Ra) of the first protective layer 160 may satisfy a range of 0.80 μm to 0.90 μm. The surface roughness of the first protective layer 160 is not particularly limited, but may be sufficient to secure adhesion with the molding layer during the process of mounting and molding a chip on the first protective layer 160.

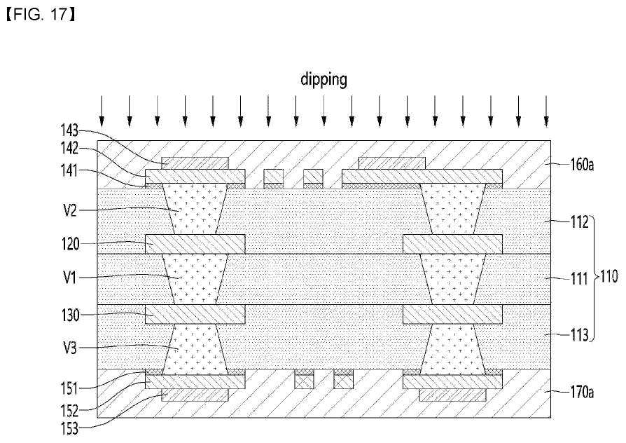

FIGS. 3 to 15 are views showing a first method for manufacturing the circuit board shown in FIG. 1 in order of process, and FIGS. 16 and 17 are views for explaining a second method for manufacturing the circuit board shown in FIG. 1.

Hereinafter, a method of manufacturing the circuit board shown in FIG. 1 will be described in detail with reference to the accompanying drawings.

Referring to FIG. 3, the embodiment prepares a first insulating layer 111. In the embodiment, when the first insulating layer 111 is prepared, the embodiment may proceed with a process of forming the first circuit pattern layer 120, the second circuit pattern layer 130 and the first via V1 on the first insulating layer 111. Briefly, when the first insulating layer 111 is prepared, the embodiment may proceed with a process of forming a seed layer (not shown) on one or both surfaces of the first insulating layer 111. In this case, the first insulating layer 111 may be CCL (Copper Clad Laminate), and thus the seed layer may be a copper foil layer constituting the CCL. Alternatively, the seed layer may be formed on at least one of the first surface and the second surface of the first insulating layer 111 through electroless plating. Next, the embodiment may proceed with a process of forming a first via hole in the first insulating layer 111 on which the seed layer is formed. Thereafter, the embodiment may proceed with a process of forming a mask (not shown) including an opening on at least one of the first and second surfaces of the first insulating layer 111 and a process of forming at least one circuit pattern layer of the first circuit pattern layer 120 and the second circuit pattern layer 130 and the first via V1 by proceeding plating in the opening of the mask.

Next, referring to FIG. 4, the embodiment may proceed with a process of laminating a second insulating layer 112 on the first surface of the first insulating layer 111 and a process of stacking a third insulating layer 113 on the second surface of the first insulating layer 111. In this case, metal layers 141 and 151 may be formed on the first surface of the second insulating layer 112 and the second surface of the third insulating layer 113, respectively. In addition, the metal layers 141 and 151 may be used as seed layers for forming the third circuit pattern layer 140 and the fourth circuit pattern layer 150. Accordingly, the metal layers 141 and 151 may also be referred to as a seed layer.

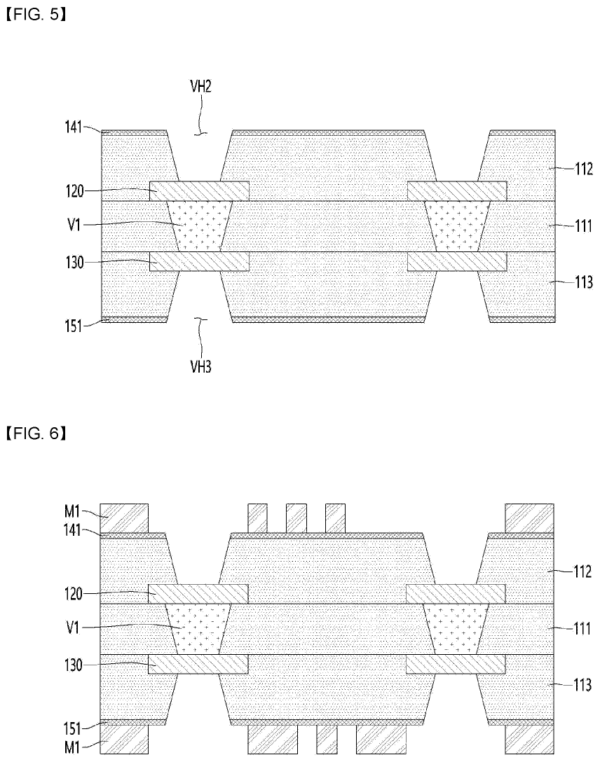

Next, referring to FIG. 5, the embodiment may proceed with a process of forming a second via hole VH2 passing through the second insulating layer 112 and the seed layer 141 disposed on the first surface thereof. And, the embodiment may proceed with a process of forming a third via hole VH3 passing through the third insulating layer 113 and the seed layer 151 disposed on the second surface thereof.

Next, referring to FIG. 6, the embodiment may proceed with a process of forming a first mask M1 on the seed layers 141 and 151. In this case, the first mask M1 disposed on the seed layer 141 on the second insulating layer 112 may include an opening (not shown) in which a region where the second via V2 and the third circuit pattern layer 140 are to be formed is open. In addition, the first mask M1 disposed on the seed layer 151 on the third insulating layer 113 may include an opening (not shown) in which a region where the third via V3 and the fourth circuit pattern layer 150 are to be formed is open.

Next, referring to FIG. 7, the embodiment may proceed with a process of electroplating using the seed layer 141 and 151. Specifically, in the embodiment, a metal material may be filled in the opening of the first mask M1 to form the first-first plating layer 142a, the first-second plating layer 152a, the second via V2 and the third via V3.

The first-first plating layer 142a and the second via V2 may be formed simultaneously. In addition, the first-first plating layer 142a and the second via V2 may be simultaneously formed of the same material.

In this case, the first-first plating layer 142a may correspond to the first pattern layer 142 of the pad 140P and the trace 140T of the third circuit pattern layer 140 described above, and the first-second plating layer 152a may correspond to the pad 150P of the fourth circuit pattern layer 150 and the first pattern layer 152 of the trace 150T. However, the thickness of the first-first plating layer 142a may be greater than the thickness of the first pattern layer 142 of the third circuit pattern layer 140, and the thickness of the first-second plating layer 152a may be greater than the thickness of the first pattern layer 152 of the fourth circuit pattern layer 150.

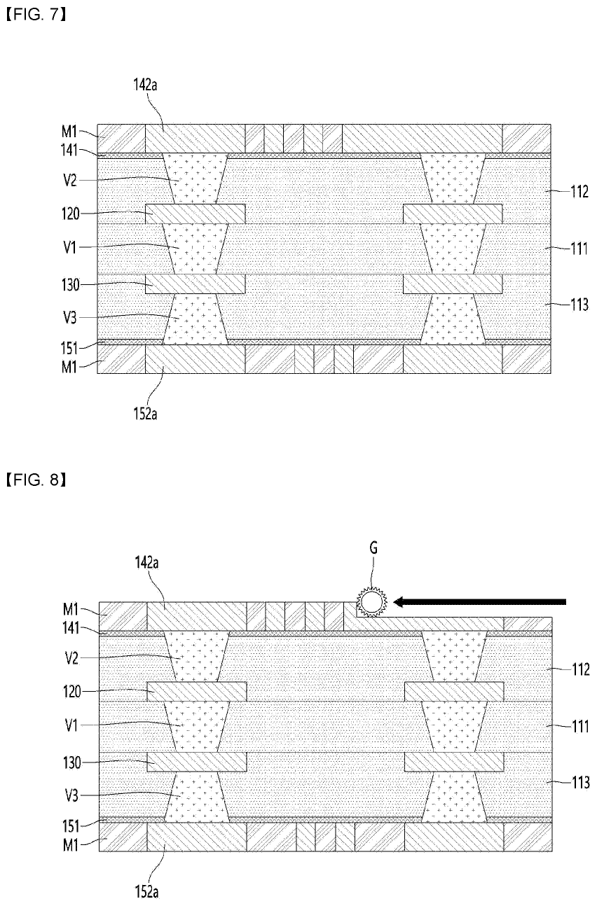

Next, referring to FIGS. 8 and 9, the embodiment may proceed with a primary grinding process. When the first-first plating layer 142a and the second via V2 are formed through plating, the upper surface of the first-first plating layer 142a may not be flat due to the dimple phenomenon of the second via hole VH2 (a phenomenon in which a central portion in a width direction of the first-first plating layer 142a or the second via V2 is concave (not shown)), and the primary grinding process may prevent warpage or poor connection between vias in a process of laminating insulating layers due to the above phenomenon.

In this case, the primary grinding process may include a first process of forming a first pattern layer 142 of the third circuit pattern layer 140 by the first-first plating layer 142a together with the first mask M1 and a second process of forming the first pattern layer 152 of the fourth circuit pattern layer 150 by grinding the first and second plating layers 152a together with the first mask M1. Each of the first pattern layer 142 of the third circuit pattern layer 140 and the first pattern layer 152 of the fourth circuit pattern layer 150 has the first thickness T1 described above by the primary grinding process. In addition, when the first grinding process is completed, the embodiment may proceed with a process of separating the first mask M1. However, the embodiment is not limited thereto, and a next process may be proceeded without the separation process of the first mask M1.

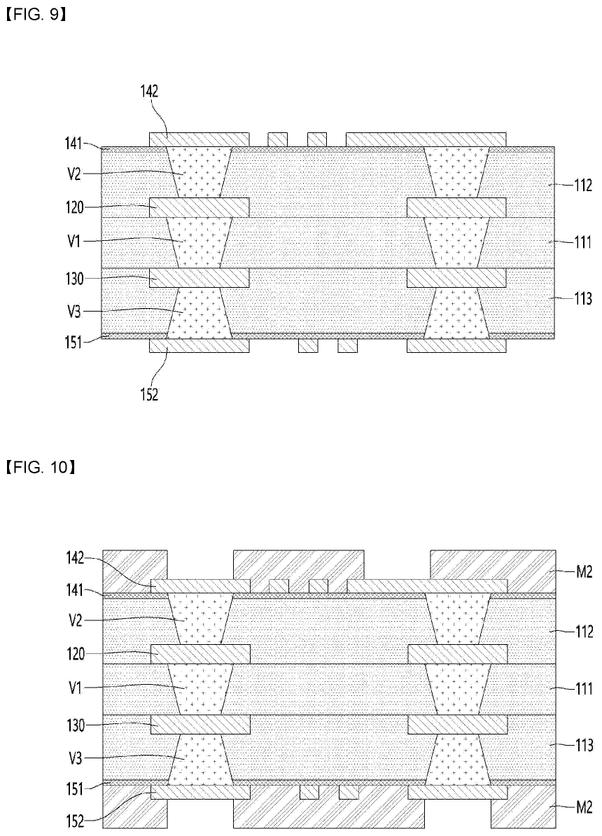

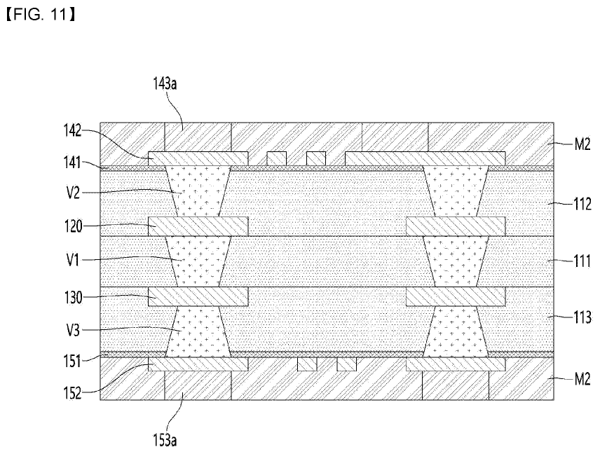

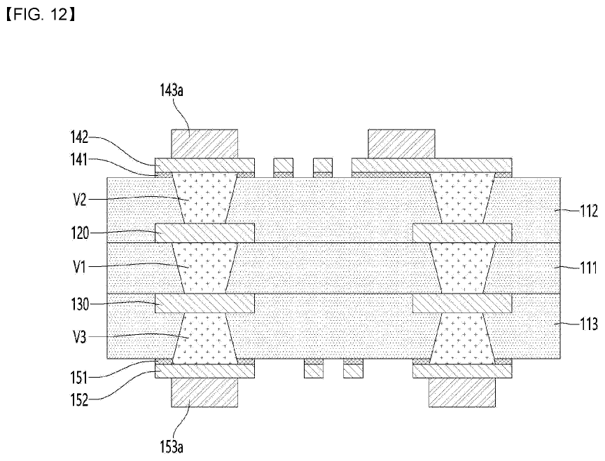

That is, referring to FIG. 10, when the primary grinding process is completed, the embodiment may proceed with a process of forming a second mask M2. In this case, the second mask M2 may be formed after removing the first mask M1, or may be formed on the first mask M1. However, the second mask M2 may have an opening having a smaller width than the width of the opening of the first mask M1. Accordingly, at least a portion of the second mask M2 may be disposed on the first pattern layer 142 of the third circuit pattern layer 140 and the first pattern layer 142 of the fourth circuit pattern layer 150.

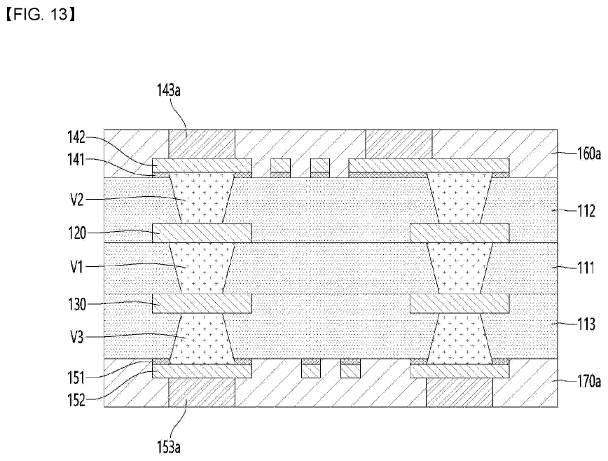

Next, referring to FIG. 11, in the embodiment, electroplating may be performed using the seed layers 141 and 151. Specifically, in the embodiment, a metal material may be filled in the opening of the second mask M2 to form the second-first plating layer 143a and the second-second plating layer 153a. In this case, the second-first plating layer 143a may correspond to the second pattern layer 143 of the pad 140P of the third circuit pattern layer 140 described above, and the second-second plating layer 153a may correspond to the 4 may correspond to the second pattern 153 of the pad 150P of the circuit pattern layer 150. However, the thickness of the second-first plating layer 143a may be greater than the thickness of the second pattern layer 143 of the third circuit pattern layer 140, and the thickness of the second-second plating layer 153a may be greater may be greater than the thickness of the second pattern layer 153 of the fourth circuit pattern layer 150.

Next, referring to FIG. 12, the embodiment may proceed with a process of removing the second mask M2. When the second mask M2 is removed, the embodiment may proceed with a process of etching the seed layers 141 and 151. Specifically, the embodiment may proceed with a process of etching and removing a region that does not overlap with the first pattern layer 141 in a vertical direction from the seed layer 141 disposed on the first surface of the second insulating layer 112. In addition, the embodiment may proceed with a process of etching and removing a region that does not overlap with the first pattern layer 151 in a vertical direction from the seed layer 151 disposed on the second surface of the third insulating layer 113.

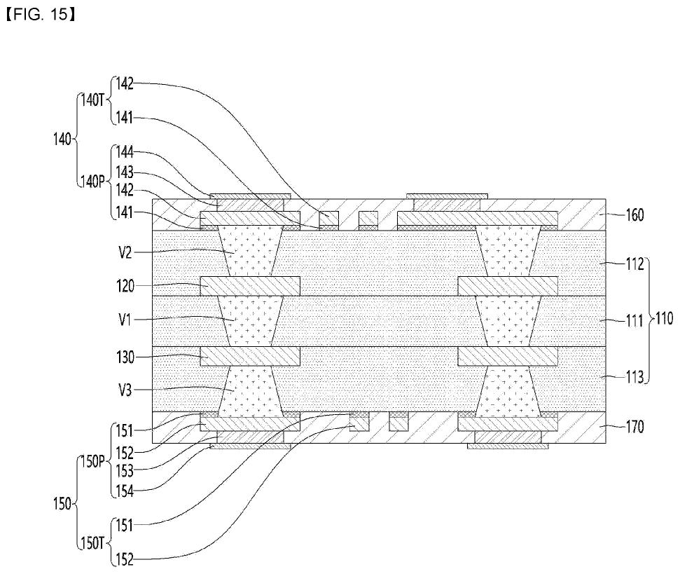

Next, referring to FIG. 13, the embodiment may proceed with a process of forming a first solder resist layer 160a on the second insulating layer 112. In this case, a height of the first solder resist layer 160a may be the same as the height of the second-first plating layer 143a. In addition, the embodiment may proceed with a process of forming a second solder resist layer 170a on the third insulating layer 113. In this case, the height of the second solder resist layer 170a may be the same as the height of the second-second plating layer 153a.

Next, referring to FIG. 14, the embodiment may proceed with a secondary grinding process. That is, the embodiment may include a first process of grinding the first solder resist layer 160a and the second-first plating layer 143a and a second process of grinding the second solder resist layer 170a and the second-second plating layer 153a. Accordingly, the embodiment may proceed with a process of forming the first protective layer 160 and the second pattern layer 143 of the pad 140P of the third circuit pattern layer 140 by grinding the first solder resist layer 160a and the second-first plating layer 143a. In addition, the embodiment may proceed with a process of forming the second protective layer 170 and the second pattern layer 153 of the pad 150P of the fourth circuit pattern layer 150 by grinding the second solder resist layer 170a and the second-second plating layer 153a.

However, the secondary grinding process may be omitted. For example, the thickness of the second-first plating layer 143a may be formed to correspond to the thickness of the second pattern layer 143 of the pad 140P of the third circuit pattern layer 140, and the thickness of the 2-2 plating layer 153a may be formed to correspond to the thickness of the second pattern layer 153 of the pad 150P of the fourth circuit pattern layer 150, and in this case, the secondary grinding process may be omitted. But, when forming the second pattern layers 143 and 153 of the pads 140P and 150P, it may be difficult to control process conditions, and accordingly, the secondary grinding process may be added to improve reliability when the thickness control of the second pattern layers 143 and 153 is incorrect.

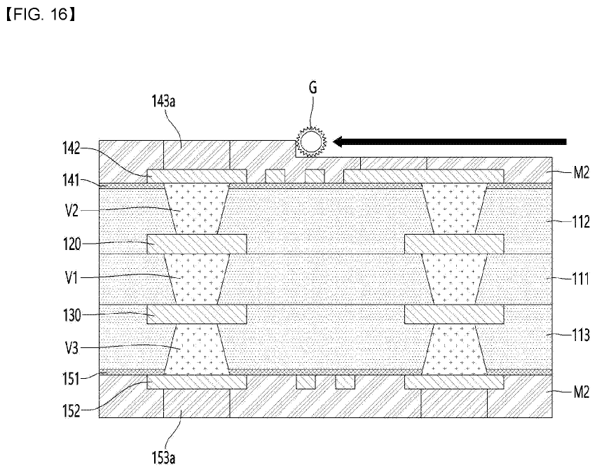

Next, referring to FIG. 15, the embodiment may proceed with a process of forming a surface treatment layer 144 on the first protective layer 160 and the second pattern layer 143 of the pad 140P of the third circuit pattern layer 140. In addition, the embodiment may proceed with a process of forming a surface treatment layer 154 on the second protective layer 170 and the second pattern layer 153 of the pad 150P of the fourth circuit pattern layer 150.

Meanwhile, the secondary grinding process in a process of manufacturing the circuit board was performed after the solder resist layers forming the first protective layer 160 and the second protective layer 170 were formed. Accordingly, the height of each of the first protective layer 160 and the second protective layer 170 may be the same as the height of each of the second pattern layers 143 and 153 by the secondary grinding process.

Alternatively, referring to FIG. 16, in another embodiment, a secondary grinding process of grinding the second mask M2 and the second-first plating layer 143a and the second-second plating layer 153a may be performed after the manufacturing of FIG. 11 is completed. Accordingly, referring to FIG. 16, the second pattern layers 143 and 153 of the pads 140P and 150P of the third circuit pattern layer 140 and the fourth circuit pattern layer 150 may be formed before the solder resist layer is formed.

Next, referring to FIG. 17, the embodiment may proceed with a process of forming first and second solder resist layers 160a and 170a covering the second pattern layers 143 and 153 on the second insulating layer 112 and the third circuit pattern layer 140. In addition, in the embodiment, the heights of the first and second solder resist layers 160a and 170a may be adjusted by performing a dipping process. That is, as shown in FIG. 17, the heights of the first protective layer 160 and the second protective layer 170 may be the same as the heights of the second patterns 142 and 153 by performing an exposure and development process instead of a grinding process.

FIG. 18 is a view showing a circuit board according to a second embodiment.

Referring to FIG. 18, structures other than the structure of the second pad and the surface treatment layer of the circuit board according to a second embodiment are the same as those of the circuit board of the first embodiment of FIGS. 1 and 2, and accordingly, only the second pad and the surface treatment layer will be described.

The circuit board includes an insulating layer 212, a first circuit pattern layer 212 corresponding to the inner circuit pattern layer, a via V2, a pad, and a first protective layer 260.

And, the circuit board includes a third circuit pattern layer 240 corresponding to a first outermost circuit pattern layer. In addition, the third circuit pattern layer 240 includes a pad 240P and a trace 240T.

The trace 240T of the third circuit pattern layer 240 may include a seed layer 241 and a first pattern layer 242. In addition, the pad 240P of the third circuit pattern layer 240 includes a seed layer 241, a first pattern layer 242, a second pattern layer 243, and a surface treatment layer 244.

In this case, in the first embodiment, the upper surface of the second pattern layer 143 of the pad 140P and the upper surface of the first protective layer 160 are positioned on the same plane.

Unlike this, in the second embodiment, an upper surface of the second pattern layer 243 of the pad 240P and an upper surface of the first protective layer 260 may be positioned on a different plane. Specifically, the upper surface of the first protective layer 260 may be positioned lower than the upper surface of the second pattern layer 243.

That is, as described above, the first protective layer 260 is formed by removing the solder resist layer through grinding or dipping. In this case, when the first protective layer 260 is formed through the grinding, the solder resist layer may be polished more than the second pattern layer 243 due to a difference in hardness between the second pattern layer 243 and the solder resist layer. Accordingly, as described above, the upper surface of the first protective layer 260 may be positioned lower than the upper surface of the second pattern layer 243.

Unlike this, the embodiment allows the upper surface of the first protective layer 260 to be positioned lower than the upper surface of the second pattern layer 243, thereby increasing the reliability of the surface of the second pattern 243. That is, as described above, the first protective layer 260 is formed by removing the solder resist layer covering the surface of the second pattern layer 243. In this case, when the grinding or dipping process is performed so that the height of the upper surface of the first protective layer 260 is the same as that of the upper surface of the second pattern layer 243, this may cause a reliability problem in that the upper surface of the second pattern layer 243 is not completely exposed depending on the process capability. Furthermore, even if the upper surface of the second pattern layer 243 is completely exposed, a resin constituting the solder resist layer may remain on the upper surface of the second pattern layer 243. Accordingly, in the embodiment, the upper surface of the first protective layer 260 is positioned lower than the upper surface of the second pattern layer 243 in order to solve the above problem.

Accordingly, the surface treatment layer 244 in the second embodiment is formed not only on the upper surface of the second pattern layer 243 but also on some side surfaces thereof. That is, the second pattern layer 243 includes a protruding region protruding from the upper surface of the first protective layer 260.

In addition, the surface treatment layer 244 includes a first portion disposed on the upper surface of the protruding region of the second pattern layer 243 and a second portion disposed on the side surface of the protruding region of the second pattern layer 243. Similarly to the first embodiment, a portion of the second portion of the second pattern layer 243 may contact the upper surface of the first protective layer 260.

In this case, a protruding region of the second pattern layer 243 may be smaller than a contact region between the second pattern layer 243 and the first protective layer 260. That is, the upper surface of the first protective layer 260 may be positioned slightly lower than the upper surface of the second pattern layer 243. When the protruding region protrudes too much from the upper surface of the first protective layer 260, a problem of disconnection may occur because adhesive members between chips mounted on the circuit board are connected to each other, and disconnection may occur between the solder balls when forming solder balls to be connected to the main printed circuit board on the circuit board.

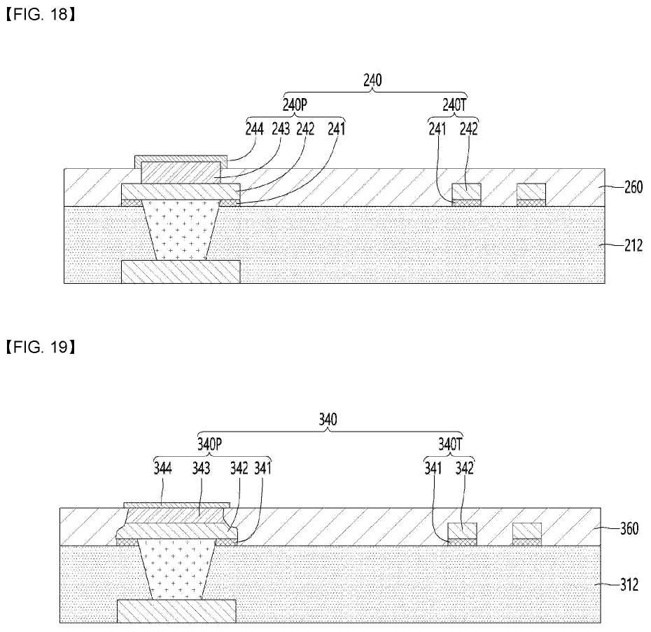

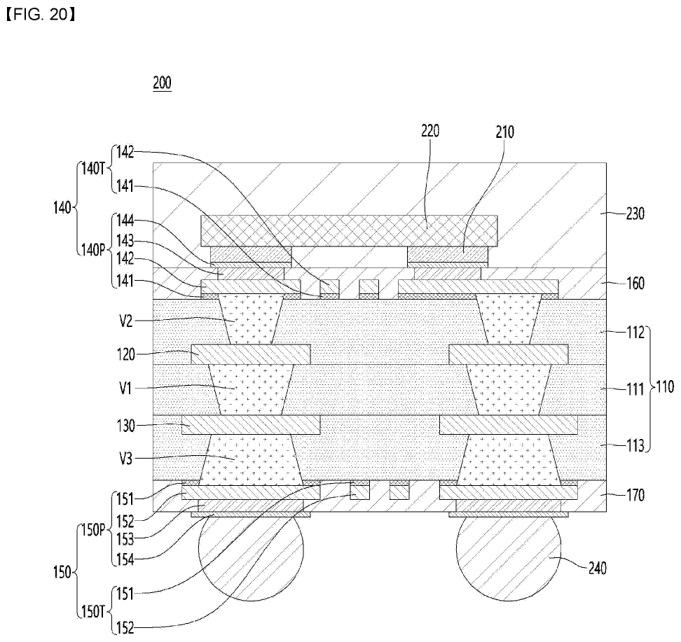

FIG. 19 is a view showing a circuit board according to a third embodiment.

Referring to FIG. 19, in a circuit board according to a third embodiment, structures other than a shape of the seed layer, the first pattern, and the second pattern constituting the pad of the third circuit pattern layer, which is the outermost circuit pattern layer are the same as those of the circuit board of the first embodiment of FIGS. 1 and 2, and accordingly, only the shape of the seed layer, the first pattern, and the second pattern constituting the pad will be described.

First, in the first embodiment, side surfaces of the seed layer 141, the first pattern layer 142, and the second pattern layer 152 of the pad 140P are perpendicular to the upper surface of the first protective layer 160.

Unlike this, in the third embodiment, at least one side surface of the seed layer 341, the first pattern layer 342, and the second pattern layer 343 of the pad 340P may include a rounded curved surface. That is, referring to FIG. 12, the embodiment includes a process of etching the seed layer in a process of manufacturing the circuit board. In this case, the embodiment adjusts the etching process time or etching conditions (eg, etching rate) of the seed layer, so that not only the seed layer, but also a part of the side surface of the first pattern layer 342 and/or a part of the side surface of the second pattern layer is also etched together.

Accordingly, in the embodiment, at least one of the side surface of the seed layer 341, the side surface of the first pattern layer 342, and the side surface of the second pattern layer 343 may be formed as a rounded curved surface by the etching.

Meanwhile, when side surfaces of the seed layer 141, the first pattern layer 142, and the second pattern layer 152 of the pad 140P are perpendicular to the upper surface of the first protective layer 160, corresponding to the first embodiment, the interface between them is filled with air in the process of forming the first protective layer 160, and accordingly, a void problem corresponding to the air space occurs.

In contrast, as in the third embodiment, when at least one side surface of the seed layer 341, the first pattern layer 342, and the second pattern layer 343 of the pad 340P has a rounded curved surface, it is possible to solve the problem of filling the air, thereby solving the reliability problem such as the void.

Meanwhile, when at least one side surface of the seed layer 341, the first pattern layer 342, and the second pattern layer 343 of the pad 340P has a rounded curved surface, it is possible to increase the contact area between the interface with the first protective layer compared to the side surface having a plane, and accordingly, delamination of the first protective layer 360 may be prevented by improving adhesion with the first protective layer 360.

An embodiment includes a circuit pattern layer. The circuit pattern layer includes an electrode layer that is a pad on which a chip is mounted. The electrode layer may include first to fourth layers. For example, the electrode layer may include a seed layer, a first pattern layer, a second pattern layer, and a surface treatment layer. In this case, the surface treatment layer may include a first portion disposed on an upper surface of the second pattern layer, and a second portion extending from the first portion and disposed on the upper surface of the protective layer. Accordingly, the embodiment can secure a wide space for arranging an adhesive member (not shown) for mounting chips by the surface treatment layer including the second portion, and thereby improve chip bonding. That is, in the embodiment, the width of the surface treatment layer is greater than the width of the second pattern layer, and thus a contact area with the adhesive member can be widened. Accordingly, according to the embodiment, the contact area with the adhesive member can be increased, and accordingly, the bonding property with the adhesive member such as a solder ball or a wire can be further improved.

In addition, since the second portion is disposed on the upper surface of the protective layer, the protective layer can support the second portion when an adhesive member (not shown) is disposed for mounting a chip. Accordingly, the embodiment can prevent the surface treatment layer from being damaged due to the adhesive member, unlike the conventional overhang structure (for example, a structure in which an end of the surface treatment layer is spaced apart without contacting the protective layer, the first pattern layer, and the second pattern layer).

In addition, in the embodiment, the upper surface of the second pattern layer may be positioned higher than the upper surface of the protective layer. Accordingly, the embodiment can prevent the resin of the protective layer from remaining on the upper surface of the second pattern layer. Accordingly, in the embodiment, the entire upper surface of the pad can be used as a space for connection with the chip. Accordingly, the embodiment can improve circuit integration and improve electrical and physical reliability. Furthermore, the embodiment allows the surface treatment layer to be disposed on a part of the side surface of the protruding second pattern layer. Accordingly, the embodiment can improve the contact area between the surface treatment layer and the second pattern layer. Therefore, in the embodiment, it is possible to solve the problem of delamination in which the surface treatment layer is separated from the second pattern layer, and thereby improve electrical and physical reliability.

In addition, in the embodiment, at least one side surface of the seed layer, the first pattern layer, and the second pattern layer constituting the pad has a rounded curved surface. Accordingly, in an embodiment, a contact area between the seed layer, the first pattern layer, and the second pattern layer and the protective layer may be increased. Accordingly, the embodiment can solve the problem of lifting between the pad and the protective layer (eg, forming an air layer between the protective layer and the pad) in a process of forming the protective layer. The embodiment can solve the delamination problem in which the protective layer is separated from the pad, and further improve the overall physical reliability and electrical reliability of the circuit board.

FIG. 20 is a view showing a package substrate according to an embodiment.

Referring to FIG. 20, the package substrate 200 includes the circuit board shown in at least one of FIGS. 1, 18 and 19. Hereinafter, a package substrate including the circuit board shown in FIG. 1 will be described for convenience of description. However, the embodiment is not limited thereto, and the package substrate described below may include the circuit board shown in FIG. 18 or 19.

In addition, the package substrate 200 includes an adhesive member disposed on the pad of the circuit board.

Specifically, the package substrate 200 may include a first adhesive member 210 disposed on the pad 140P of the third circuit pattern layer 140 of the circuit board. In addition, the package substrate 200 may include a second adhesive member 240 disposed on the pad 150P of the fourth circuit pattern layer 150 of the circuit board.

The first adhesive member 210 and the second adhesive member 240 may have a different shape. For example, the first adhesive member 210 may have a hexahedral shape. For example, a cross section of the first adhesive member 210 may have a rectangular shape. For example, the cross section of the first adhesive member 210 may include a rectangular or square shape. The second adhesive member 240 may have a spherical shape. For example, the cross section of the second adhesive member 240 may include a circular shape or a semicircular shape. For example, the cross section of the second adhesive member 240 may have a partially or entirely rounded shape. For example, the cross-sectional shape of the second adhesive member 240 may include a flat surface on one side and a curved surface on the other side opposite to the one side. Meanwhile, the second adhesive member 240 may be a solder ball, but is not limited thereto.

A chip 220 may be mounted on the first adhesive member 210. For example, the chip 220 may include a drive IC chip. For example, the chip 220 may refer to various chips including sockets or devices other than a drive IC chip. For example, the chip 220 may include at least one of a diode chip, a power IC chip, a touch sensor IC chip, an MLCC chip, a BGA chip, and a chip capacitor. For example, the chip 220 may be a power management integrated circuit (PMIC). For example, the chip 220 may be a memory chip such as a volatile memory (eg, DRAM), a non-volatile memory (eg, ROM), or a flash memory. For example, the chip 220 is an application processor (AP) chip such as a central processor (eg, CPU), a graphic processor (eg, GPU), a digital signal processor, a cryptographic processor, a microprocessor, and a microcontroller, or a logic chip such as an analog-to-digital converter or an application-specific IC (ASIC). Here, although only one chip is illustrated as being mounted on the package substrate 200 on the drawing, it is not limited thereto. For example, the third circuit pattern layer 140 of the circuit board may include a plurality of pads spaced apart from each other. In addition, a chip may be mounted on each of the plurality of pads. For example, the plurality of chips may include a first AP chip corresponding to a central processor (CPU) and a second AP chip corresponding to a graphics processor (GPU).

A molding layer 230 may be formed on the circuit board. The molding layer 230 may be disposed to cover the mounted chip 220. For example, the molding layer 230 may be EMC (Epoxy Mold Compound) formed to protect the mounted chip 220, but is not limited thereto.

Meanwhile, in the embodiment, a first spacing between the plurality of pads 140P of the third circuit pattern layer 140 may be different from a second spacing between the plurality of pads 150P of the fourth circuit pattern layer 150. For example, a first spacing between the plurality of pads 140P of the third circuit pattern layer 140 may correspond to a terminal (not shown) of the chip 220. In addition, the second spacing of the plurality of pads 150P of the fourth circuit pattern layer 150 may correspond to a terminal (not shown) of an external board (not shown) attached through the second adhesive member 240. In this case, the first spacing between the plurality of pads 140P of the third circuit pattern layer 140 may be smaller than the second spacing between the plurality of pads 150P of the fourth circuit pattern layer 150. For example, the third circuit pattern layer 140 may be a fine pattern corresponding to a terminal (not shown) of the chip 220.

The vias V1, V2, and V3, the first circuit pattern layer 120, and the second circuit pattern layer 130 of the circuit board may connect between the plurality of pads 140P of the third circuit pattern layer 140 and the plurality of pads 150P of the fourth circuit pattern layer 150 having different spacings.

In this case, the vias V1, V2, and V3 may have different widths to connect the pads 140P having a relatively small first spacing and the pads 150P having a relatively great second spacing.

For example, the second via V2 may have a width corresponding to the first spacing between the pads 140P. For example, the third via V2 may have a width corresponding to the second spacing between the pads 150P. For example, the width of the first via V1 may be between the width of the second via V2 and the width of the third via V3. For example, the widths of the vias V1, V2, and V3 in the embodiment may gradually decrease as they are closer to the pad 140P or further away from the pad 150P. For example, in the embodiment, the second via V2 may have the smallest width, the third via V3 may have the greatest width, and the first via V1 may have a width between the second via V2 and the third via V3.

Features, structures, effects, etc. described in the above embodiments are included in at least one embodiment, and are not necessarily limited to only one embodiment. Furthermore, features, structures, effects, etc. illustrated in each embodiment can be combined or modified for other embodiments by those of ordinary skill in the art to which the embodiments belong. Accordingly, the contents related to such combinations and modifications should be interpreted as being included in the scope of the embodiments.

In the above, the embodiment has been mainly described, but this is only an example and does not limit the embodiment, those of ordinary skill in the art to which the embodiment pertains will appreciate that various modifications and applications not illustrated above are possible without departing from the essential characteristics of the present embodiment. For example, each component specifically shown in the embodiment can be implemented by modification. And differences related to such modifications and applications should be construed as being included in the scope of the embodiments set forth in the appended claims.

1. A circuit board comprising:
an insulating layer;
an electrode layer disposed on the insulating layer; and
a protective layer disposed on the insulating layer and including an opening vertically overlapping at least a portion of an upper surface of the electrode layer;
wherein the electrode layer includes:
a first layer disposed on the insulating layer;
a second layer disposed on the first layer; and
a third layer disposed on the second layer; and
a fourth layer disposed on the third layer,
wherein a width of the second layer is greater than a width of the third layer,
wherein a thickness of the second layer is greater than a thickness of the third layer, and
wherein a height of an upper surface of the protective layer is equal to or less than a height of an upper surface of the third layer.

2. The circuit board of claim 1, wherein the first layer is a seed layer disposed on an upper surface of the insulating layer,
wherein the second layer is a first pattern layer of a circuit pattern layer disposed on the seed layer,
wherein the third layer is a second pattern layer of the circuit pattern layer disposed on the first pattern layer of the circuit pattern layer, and
wherein the fourth layer is a surface treatment layer disposed on the second pattern layer of the circuit pattern layer.

3. The circuit board of claim 1, wherein the electrode layer is a pad on which a chip is mounted.

4. The circuit board of claim 1, wherein the second layer of the electrode layer includes a same metal material as a metal material of the third layer of the electrode layer.

5. The circuit board of claim 1, wherein the second layer of the electrode layer has a greater width than a width of the fourth layer of the electrode layer.

6. The circuit board of claim 1, wherein the thickness of the second layer of the electrode layer is greater than a thickness of the fourth layer of the electrode layer.

7. The circuit board of claim 1, wherein the upper surface of the protective layer is positioned lower than the third layer of the electrode layer, and
wherein the third layer of the electrode layer includes a protruding region protruding from the upper surface of the protective layer.

8. The circuit board of claim 7, wherein the fourth layer of the electrode layer includes:
a first portion disposed on an upper surface of the third layer of the electrode layer; and
a second portion extending from the first portion and disposed on a side surface of the protruding region of the third layer.

9. The circuit board of claim 1, wherein the fourth layer of the electrode layer includes:
a first portion disposed on an upper surface of the third layer of the electrode layer; and
a second portion extending from the first portion and disposed on the upper surface of the protective layer.

10. The circuit board of claim 1, wherein at least one side surface of the second layer and the third layer of the electrode layer includes a curved surface.

11. The circuit board of claim 1, wherein the insulating layer includes a first insulating layer and a second insulating layer disposed on the first insulating layer, and
wherein the first layer of the electrode layer is disposed on the second insulating layer.

12. The circuit board of claim 11, further comprising:
an interlayer circuit pattern disposed between the first insulating layer and the second insulating layer, and
wherein a surface roughness (Ra) of the interlayer circuit pattern is different from a surface roughness (Ra) of the second layer of the electrode layer.

13. The circuit board of claim 12, wherein the surface roughness (Ra) of the interlayer circuit pattern is greater than the surface roughness (Ra) of the second layer of the electrode layer.

14. The circuit board of claim 13, wherein a surface roughness (Ra) of the protective layer is smaller than the surface roughness (Ra) of the interlayer circuit pattern and greater than the surface roughness (Ra) of the second layer of the electrode layer.

15. A semiconductor package comprising:
an insulating layer;
an electrode layer disposed on the insulating layer;
a protective layer disposed on the insulating layer and including an opening vertically overlapping at least a portion of an upper surface of the electrode layer;
a first adhesive member disposed on an electrode layer overlapping the opening of the protective layer;
a semiconductor chip disposed on the first adhesive member; and
a molding layer molding the semiconductor chip;
wherein the electrode layer includes:
a first layer disposed on the insulating layer;
a second layer disposed on the first layer; and
a third layer disposed on the second layer; and
a fourth layer disposed on the third layer,
wherein a width of the second layer is greater than a width of the third layer,
wherein a thickness of the second layer is greater than a thickness of the third layer, and
wherein a height of an upper surface of the protective layer is equal to or less than a height of an upper surface of the third layer.

16. The semiconductor package of claim 15, wherein the first layer is a seed layer disposed on an upper surface of the insulating layer,
wherein the second layer is a first pattern layer of a circuit pattern layer disposed on the seed layer,
wherein the third layer is a second pattern layer of the circuit pattern layer disposed on the first pattern layer of the circuit pattern layer, and
wherein the fourth layer is a surface treatment layer disposed on the second pattern layer of the circuit pattern layer.

17. The semiconductor package of claim 15, wherein the second layer of the electrode layer includes a same metal material as a metal material of the third layer of the electrode layer.

18. The semiconductor package of claim 15, wherein the second layer of the electrode layer has a width greater than a width of the fourth layer of the electrode layer,
wherein a thickness of the second layer of the electrode layer is greater than a thickness of the fourth layer of the electrode layer.

19. The semiconductor package of claim 15, wherein an upper surface of the protective layer is positioned lower than the third layer of the electrode layer,
wherein the third layer of the electrode layer includes a protruding region protruding from the upper surface of the protective layer, and
wherein the fourth layer of the electrode layer includes:
a first portion disposed on an upper surface of the third layer of the electrode layer; and
a second portion extending from the first portion and disposed on a side surface of the protruding region of the third layer.

20. The semiconductor package of claim 15, wherein the fourth layer of the electrode layer includes:
a first portion disposed on an upper surface of the third layer of the electrode layer; and
a second portion extending from the first portion and disposed on an upper surface of the protective layer.
